(19) United States
(12) Patent Application Publication
(10) Pub. No.: US 2024/0276769 A1
(43) Pub. Date: Aug. 15, 2024

(54) DISPLAY DEVICE

(71) Applicant: Samsung Display Co., LTD., Yongin-si (KR)

(72) Inventors: Sun Kwun SON, Yongin-si (KR); Sang Yong NO, Yongin-si (KR); Dong Hee SHIN, Yongin-si (KR)

(73) Assignee: Samsung Display Co., LTD., Yongin-si (KR)

(21) Appl. No.: 18/509,307

(22) Filed: Nov. 15, 2023

(30) Foreign Application Priority Data
Feb. 13, 2023 (KR) 10-2023-0018942

(51) Int. Cl. H10K 59/121; G09G 3/3233; H10K 59/131

(52) U.S. Cl. CPC H10K 59/1213; G09G 3/3233; H10K 59/131; G09G 2300/0426; G09G 2300/0819; G09G 2300/0842

(57) ABSTRACT

An embodiment provides a display device including a pixel circuit layer including a base layer and a pixel circuit; and a light emitting element disposed on the pixel circuit layer and including a first electrode, a second electrode, and a light emitting layer electrically connected the first electrode and the second electrode. The pixel circuit includes a first transistor. The first transistor includes a first gate electrode, a first active layer, a first source electrode, and a first drain electrode. The first electrode forms an open area. The first gate electrode and the open area overlap each other in a plan view.

### CROSS-REFERENCE TO RELATED APPLICATION(S)

This application claims priority to and benefits of Korean patent application No. 10-2023-0018942 under 35 U.S.C. § 119, filed on Feb. 13, 2023, in the Korean Intellectual Property Office, the entire contents of which are incorporated herein by reference.

### BACKGROUND

### 1. Technical Field

The disclosure relates to a display device.

### 2. Description of the Related Art

As information technology has developed, the importance of a display device, which is a connection medium between a user and information, has been highlighted. The display device may comprise a light emitting element capable of emitting light and a pixel circuit for driving the light emitting element.

Electrical signals for driving the light emitting element may be applied from a designed pixel circuit by two or more electrode patterns. The electrical signals may interfere with each other, and, a risk such as signal delay may occur. Accordingly, in order to provide a high-quality display device, an electrode structure with improved reliability of electrical signals is required.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device with improved reliability of an electrical signal within the display device.

An embodiment provides a display device that may comprise a pixel circuit layer comprising a base layer and a pixel circuit; and a light emitting element disposed on the pixel circuit layer and comprising a first electrode; a second electrode; and a light emitting layer electrically connected to the first electrode and the second electrode. The pixel circuit may comprise a first transistor, and the first transistor may comprise a first gate electrode; a first active layer; a first source electrode; and a first drain electrode. The first electrode may form an open area. The first gate electrode and the open area may overlap each other in a plan view.

According to an embodiment, the first gate electrode may be an uppermost conductive layer of the pixel circuit layer in an area including the first gate electrode.

According to an embodiment, the pixel circuit layer may comprise a lower auxiliary electrode layer; an active layer; and an interlayer conductive layer that form the pixel circuit. The lower auxiliary electrode layer may be closer to the base layer than the interlayer conductive layer. At least a portion of the first gate electrode may be formed by the interlayer conductive layer.

According to an embodiment, the first gate electrode may overlap the second electrode in a plan view.

According to an embodiment, the first gate electrode may form a capacitance with the second electrode.

According to an embodiment, the display device may further comprise a bridge electrode layer, the bridge electrode layer and the first electrode being disposed on a same layer and electrically connected to each other. The first electrode may form a peripheral opening area. The peripheral opening area may surround the bridge electrode layer.

According to an embodiment, the pixel circuit may comprise a second transistor that comprises a second gate electrode; a second active layer; a second source electrode; and a second drain electrode. The second source electrode may be electrically connected to the first gate electrode.

According to an embodiment, the first gate electrode may be electrically connected to the second source electrode without passing through a conductive layer disposed on a different layer from a layer of the first gate electrode.

According to an embodiment, the pixel circuit may further comprise a gate bridge formed by the lower auxiliary electrode layer. The first gate electrode may be electrically connected to the second source electrode through the gate bridge.

According to an embodiment, the pixel circuit may further comprise a connection electrode layer formed by the interlayer conductive layer. The connection electrode layer, the gate bridge, and the second source electrode may be electrically connected to each other.

According to an embodiment, the first transistor may be a driving transistor. The second transistor may be a switching transistor.

According to an embodiment, the display device may further comprise a first power line and a second power line disposed on the base layer. The pixel circuit may comprise a third transistor that may comprise a third gate electrode; a third active layer; a third source electrode; and a third drain electrode. The third source electrode may be electrically connected to the first source electrode. The first power line may be electrically connected to the pixel circuit. The pixel circuit may be electrically connected to the second electrode. The second power line may be electrically connected to the first electrode.

According to an embodiment, the pixel circuit may comprise a first pixel circuit of a first sub-pixel; a second pixel circuit of a second sub-pixel; and a third pixel circuit of a third sub-pixel. The first power line may extend in a first direction. The second power line may comprise a (2-1)-th power line extending in the first direction and a (2-2)-th power line extending in a second direction different from the first direction. The pixel circuit may comprise a storage capacitor. Respective storage capacitors of the first pixel circuit, the second pixel circuit, and the pixel circuit may be sequentially disposed in the second direction.

According to an embodiment, a shape of the open area may correspond to a shape of the first gate electrode.

According to an embodiment, a shape of the open area and a shape of the first gate electrode may be substantially the same.

According to an embodiment, the first electrode may be a cathode electrode electrically connected to the light emitting layer. The second electrode may be an anode electrode electrically connected to the light emitting layer. The first electrode may be disposed between the second electrode and the base layer.

According to an embodiment, the display device may further comprise a pixel defining film disposed on the pixel circuit layer; a separator disposed on the pixel defining film and having a substantially under-cut shape; and a residual conductive layer disposed on the separator. The residual conductive layer and the second electrode may comprise a same material. The residual conductive layer and the second electrode may be physically spaced apart from each other. The separator may overlap the first gate electrode and the open area in a plan view.

According to an embodiment, the light emitting element may be an organic light emitting diode (OLED).

An embodiment provides a display device that may comprise a pixel circuit layer comprising a base layer and a pixel circuit disposed on the base layer; and a light-emitting-element layer comprising a light emitting element disposed on the pixel circuit layer and comprising a cathode electrode; an anode electrode; and a light emitting layer electrically connected to the cathode electrode and the anode electrode. The pixel circuit layer may comprise a lower auxiliary electrode layer; an active layer; and an interlayer conductive layer. The interlayer conductive layer may be closer to the light-emitting-element layer than the lower auxiliary electrode layer. The pixel circuit may comprise a first transistor and a second transistor. The first transistor may comprise a first gate electrode; a first active layer; a first source electrode; and a first drain electrode. The second transistor may comprise a second gate electrode; a second active layer; a second source electrode; and a second drain electrode. The second source electrode and the first gate electrode may be electrically connected to each other. The first gate electrode and the second gate electrode may be formed by the interlayer conductive layer. The first active layer and the second active layer may be formed by the active layer. The cathode electrode and at least a portion of the interlayer conductive layer forming the second gate electrode may not overlap each other in a plan view.

An embodiment provides a display device that may comprise a pixel circuit layer comprising a base layer and a pixel circuit; and a light emitting element disposed on the pixel circuit layer and may comprise a first electrode; a second electrode; and a light emitting layer electrically connected the first electrode and the second electrode. The pixel circuit may comprise a driving transistor. The first electrode may form an open area. The open area may surround an edge of a gate electrode of the driving transistor in a plan view.

According to the embodiment of the disclosure, it is possible to provide a display device with improved reliability of an electrical signal within the display device.

### BRIEF DESCRIPTION OF THE DRAWINGS

Illustrative, non-limiting embodiments will be more clearly understood from the following detailed description in conjunction with the accompanying drawings in which:

FIG. 1 illustrates a block diagram of a display device according to an embodiment.

FIG. 2 illustrates a schematic cross-sectional view of a display device according to an embodiment.

FIG. 3 illustrates a pixel circuit comprised in a sub-pixel according to an embodiment.

FIG. 4 illustrates a schematic cross-sectional view of a stacked structure of a display device according to an embodiment.

FIG. 5 and FIG. 6 illustrate schematic plan views of an electrode structure according to an embodiment.

FIG. 7 to FIG. 9 illustrate schematic cross-sectional views of a display device according to an embodiment.

FIG. 10 illustrates a schematic top plan view of an electrode structure according to an embodiment.

FIG. 11 and FIG. 12 illustrate schematic cross-sectional views of a display device according to an embodiment.

### DETAILED DESCRIPTION OF THE EMBODIMENTS

Since the disclosure may be variously modified and have various forms, embodiments will be illustrated and described in detail in the following. This, however, by no means restricts the disclosure to the disclosed embodiments, and it is to be understood as embracing all comprised in the spirit and scope of the disclosure changes, equivalents, and substitutes.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the disclosure.

Singular forms are intended to comprise plural forms unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.

In the specification and the claims, the phrase “at least one of” is intended to include the meaning of “at least one selected from the group of” for the purpose of its meaning and interpretation. For example, “at least one of A and B” may be understood to mean “A, B, or A and B.

In the disclosure, it will be understood that when an element or layer is referred to as being “on”, “connected to” or “coupled to” another element or layer, it can be directly on, connected or coupled to the other element or layer or intervening elements or layers may be present.

In the disclosure, it should be understood that the term “comprise”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance.

It will be understood that when an element such as a layer, film, region, area, or substrate is referred to as being “on” another element, it can be directly on the other element or intervening elements may also be present. In the specification, when a portion of a layer, film, region, area, plate, or the like is referred to as being formed “on” another portion, the formed direction is not limited to an upper direction but comprises a lateral or lower direction. In contrast, when an element of a layer, film, region, area, plate, or the like is referred to as being “below” another element, it may be directly below the other element, or intervening elements may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Embodiments described in the disclosure are described with reference to schematic plan views and schematic cross-sectional views that are illustrated schematic diagrams. Accordingly, shapes of the views may vary depending on manufacturing technologies and/or tolerances. Thus, embodiments are not limited to illustrated forms and also include variations in form produced according to manufacturing processes. Therefore, regions illustrated in the drawings are examples, and the shapes of the regions illustrated in the drawings are intended to illustrate the example shapes of the regions of elements and not to limit the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosure relates to a display device. Hereinafter, a display device according to an embodiment will be described with reference to the accompanying drawings.

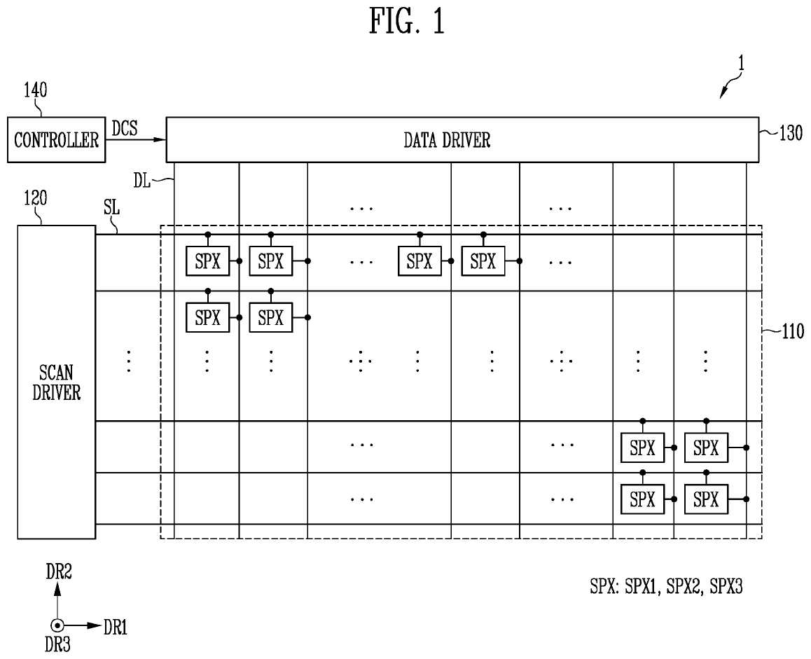

Referring to FIG. 1, a display device 1 according to an embodiment will be described. FIG. 1 illustrates a block diagram of a display device according to an embodiment.

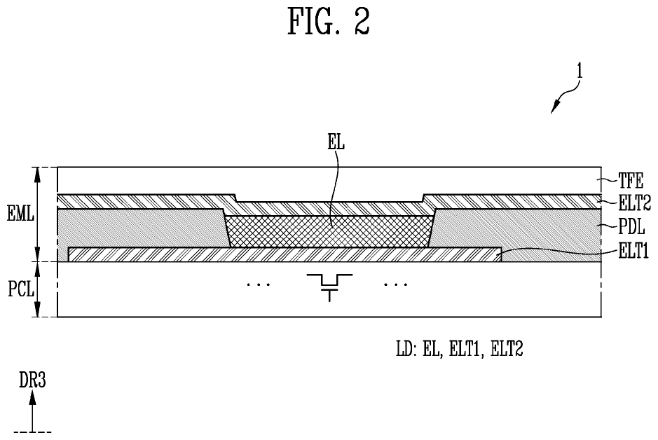

The display device 1 is configured to emit light. The display device 1 may be an electronic device using a light emitting element LD (see FIG. 2) as a light source. According to the embodiment, the display device 1 may comprise a pixel part 110, a scan driver 120, a data driver 130, and a controller 140.

The pixel part 110 may comprise sub-pixels SPX connected to a scan line SL and a data line DL. In an embodiment, one or more of the sub-pixels SPX may form (or configure) a pixel (or a pixel unit). Each of the sub-pixels SPX may be one of first to third sub-pixels SPX1, SPX2, and SPX3. For example, the sub-pixel SPX may comprise a first sub-pixel SPX1 emitting light of a first color (for example, red), a second sub-pixel SPX2 emitting light of a second color (for example, green), and a third sub-pixel SPX3 emitting light of a third color (for example, blue). However, the disclosure is not limited to the example described above.

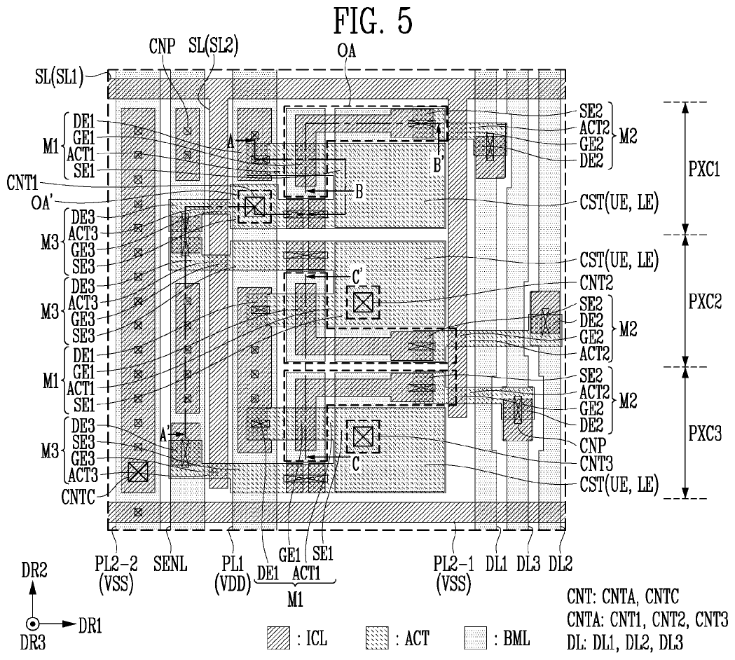

The scan driver 120 may be disposed at one side or a side of the pixel part 110. The scan driver 120 may receive a first control signal SCS from the controller 140. The scan driver 120 may provide a scan signal to the sub-pixel SPX. The scan driver 120 may supply a scan signal to the scan lines SL in response to the first control signal SCS. For example, the scan signal may be provided to the sub-pixel SPX through a first scan line SL1 (see FIG. 5) extending in a first direction DR1 and a second scan line SL2 (see FIG. 5) extending in a second direction DR2.

The first control signal SCS may be a signal for controlling driving timing of the scan driver 120. The first control signal SCS may comprise a scan start signal for the scan signal and clock signals. The scan signal may be set to a gate-on level corresponding to a type of transistor to which a corresponding scan signal is supplied.

The data driver 130 may be disposed at one side or a side of the pixel part 110. The data driver 130 may receive a second control signal DCS from the controller 140. The data driver 130 may provide a data signal to the sub-pixel SPX. The data driver 130 may supply the data signal to the data line DL in response to the second control signal DCS. For example, the second control signal DCS may be provided to the sub-pixel SPX through the data line DL. The second control signal DCS may be a signal for controlling driving timing of the data driver 130.

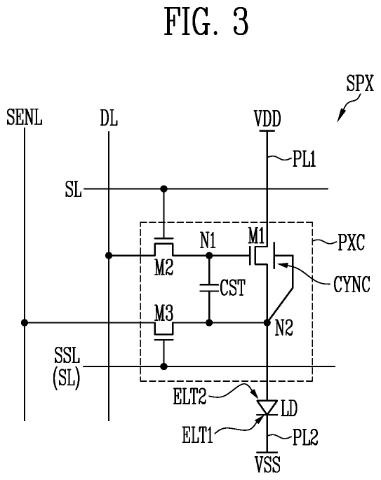

In an embodiment, the display device 1 may further comprise a compensator (not shown). The compensator may receive a third control signal for sensing and deterioration compensation of the sub-pixels SPX from the controller 140. The compensator may receive a sensing value (current or voltage information) extracted from the sub-pixel SPX through a sensing line SENL (see FIG. 3). The compensator may generate a compensation value for compensating deterioration of the sub-pixel SPX based on the sensing value.

A portion of the scan line SL (the first scan line SL1) may extend in the first direction DR1 to be electrically connected to the sub-pixel SPX of the corresponding pixel row through another portion of the scan line SL (the second scan line SL2) extending in the second direction DR2, thereby supplying the scan signal to the corresponding sub-pixel SPX.

The data line DL may extend along the pixel column (for example, in the second direction DR2) and be electrically connected to the sub-pixel SPX. The data line DL may supply a data signal to the connected sub-pixel SPX.

Here, the pixel row direction is a horizontal direction and may mean the first direction DR1, and the pixel column direction is a vertical direction and may mean the second direction DR2.

In FIG. 1, the scan driver 120, the data driver 130, and the controller 140 are separately shown, but at least some of the scan driver 120, the data driver 130, and the controller 140 may be integrated into one module or an integrated circuit chip (IC chip).

Hereinafter, a stacked structure comprising a light emitting element LD for forming the sub-pixel SPX according to the embodiment will be described with reference to FIG. 2. FIG. 2 illustrates a schematic cross-sectional view of a display device according to an embodiment.

In an embodiment, the display device 1 (or the sub-pixel SPX) may comprise the light emitting elements LD. According to the embodiment, the light emitting elements LD may be provided in various forms. In the specification, for better understanding and ease of description, an embodiment in which the light emitting elements LD are organic light emitting diodes (OLED) will be described as a reference.

Referring to FIG. 2, the display device 1 may comprise a pixel circuit layer PCL and a light-emitting-element layer EML.

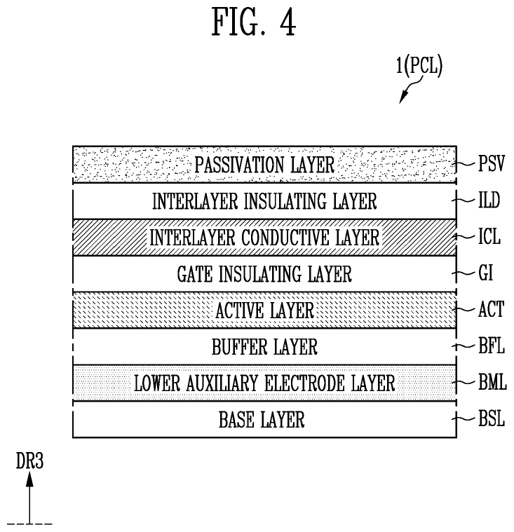

The pixel circuit layer PCL may be a layer comprising a pixel circuit PXC (see FIG. 3) for driving the light emitting elements LD. The pixel circuit layer PCL may comprise a base layer BSL (see FIG. 4), conductive layers for forming pixel circuits, and insulating layers disposed between the conductive layers. A detailed description of the stacked structure for forming the pixel circuit layer PCL will be described later with reference to the drawings after FIG. 4.

In an embodiment, the base layer BSL may be a base substrate or a base member for supporting the display device 1. The substrate may be a rigid substrate of a glass material. By way of example, the base layer BSL may be a flexible substrate that is bendable, foldable, or rollable. The base layer BSL may comprise an insulating material such as a polymer resin such as a polyimide.

In an embodiment, the pixel circuit PXC may comprise a thin film transistor, and may be electrically connected to the light emitting elements LD to provide an electrical signal to the light emitting elements LD to emit light.

The light-emitting-element layer EML may be disposed on the pixel circuit layer PCL. In an embodiment, the light-emitting-element layer EML may comprise the light emitting element LD, a pixel defining film PDL, and an encapsulation film TFE.

The light emitting element LD may be disposed on the pixel circuit layer PCL. In an embodiment, the light emitting element LD may comprise a first electrode ELT1, a light emitting layer EL, and a second electrode ELT2. In an embodiment, the light emitting layer EL may be disposed in an area defined by the pixel defining film PDL. One surface or a surface of the light emitting layer EL may be electrically connected to the first electrode ELT1, and the other surface of the light emitting layer EL may be electrically connected to the second electrode ELT2.

The first electrode ELT1 may be a common electrode (or a cathode electrode) to electrically connect the light emitting layer EL, and the second electrode ELT2 may be an anode electrode to electrically connect light emitting layer EL.

According to the embodiment, the first electrode ELT1 may be more adjacent to the pixel circuit layer PCL than the second electrode ELT2. According to the embodiment, the first electrode ELT1 for supplying a cathode signal may be disposed below the second electrode ELT2 for supplying an anode signal. For example, the first electrode ELT1 may be disposed between the pixel circuit layer PCL and the second electrode ELT2.

In an embodiment, the first electrode ELT1 and the second electrode ELT2 may comprise a conductive material. For example, the first electrode ELT1 and/or the second electrode ELT2 may comprise at least one of various metallic materials such as gold (Au), silver (Ag), aluminum (Al), molybdenum (Mo), chromium (Cr), titanium (Ti), nickel (Ni), neodymium (Nd), copper (Cu), and platinum (Pt), or an alloy thereof. In an embodiment, the first electrode ELT1 and/or the second electrode ELT2 may comprise at least one of various transparent conductive materials comprising one of a silver nanowire (AgNW), an indium tin oxide (ITO), an indium zinc oxide (IZO), an indium gallium zinc oxide (IGZO), an antimony zinc oxide (AZO), an indium tin zinc oxide (ITZO), a zinc oxide (ZnO), a tin oxide (SnO₂), a carbon nano tube, and a graphene.

The light emitting layer EL may have a multi-layered thin film structure comprising a light generation layer. The light emitting layer EL may comprise a hole injection layer for injecting holes, a hole transport layer for increasing chance of recombination between holes and electrons by having excellent hole transport and blocking movement of electrons that are not be combined in a light generation layer, a light generation layer that emits light by recombination of injected electrons and holes, a hole blocking layer for blocking movement of holes that are not be combined in a light generation layer, an electron transport layer for smoothly transporting electrons to the light generation layer, and an electron injection layer for injecting electrons. The light emitting layer EL may emit light based on electrical signals provided from the first electrode ELT1 and the second electrode ELT2.

The pixel defining film PDL may be disposed on the pixel circuit layer PCL to define a position at which the light emitting layer EL is disposed. The pixel defining film PDL may comprise an organic material. In an embodiment, the pixel defining film PDL may comprise at least one of an acrylic resin, an epoxy resin, a phenol resin, a polyamide resin, and a polyimide resin. However, the disclosure is not limited thereto.

The encapsulation film TFE may be disposed on the light emitting element LD (for example, the second electrode ELT2). The encapsulation film TFE may offset a level difference generated by the light emitting element LD and the pixel defining film PDL. The encapsulation film TFE may comprise insulating films covering the light emitting element LD. In an embodiment, the encapsulation film TFE may have a structure in which an inorganic film and an organic film are alternately stacked each other. In an embodiment, the encapsulation film TFE may be a thin film encapsulation film.

Hereinafter, a pixel circuit PXC according to an embodiment will be described with reference to FIG. 3. FIG. 3 illustrates a pixel circuit comprised in a sub-pixel according to an embodiment. Referring to FIG. 3, the sub-pixel SPX may comprise the pixel circuit PXC. The pixel circuit PXC is configured to drive the light emitting elements LD. In an embodiment, each of the sub-pixels SPX for forming one pixel unit may comprise the pixel circuit PXC.

The sub-pixel SPX may be electrically connected to the scan line SL, the data line DL, a first power line PL1, and a second power line PL2. The sub-pixel SPX may be further electrically connected to the sensing line SENL.

The sub-pixel SPX may comprise the light emitting elements LD configured to emit light corresponding to a data signal provided from the data line DL.

The pixel circuit PXC may be disposed between the first power line PL1 and the light emitting elements LD. The pixel circuit PXC may be electrically connected to the scan line SL to which a first scan signal is supplied and the data line DL to which a data signal is supplied. The pixel circuit PXC may be electrically connected to a control line SSL to which a second scan signal is supplied, and may be electrically connected to the sensing line SENL connected to a reference power source (or an initialization power source) or a sensing circuit. In an embodiment, the second scan signal may be the same as or different from the first scan signal. In case that the second scan signal is the same as the first scan signal, the control line SSL may be integral with the scan line SL.

The pixel circuit PXC may comprise one or more circuit elements. For example, the pixel circuit PXC may comprise a first transistor M1, a second transistor M2, a third transistor M3, and a storage capacitor CST.

The first transistor M1 may be electrically connected between the first power line PL1 and a second node N2. The second node N2 may be a node at which the pixel circuit PXC and the light emitting element LD are connected. For example, the second node N2 may be a node to which one electrode (for example, a first source electrode SE1 (see FIG. 5)) of the first transistor M1 and the second electrode ELT2 of the light emitting element LD are connected. A first gate electrode GE1 (see FIG. 5) of the first transistor M1 may be electrically connected to a first node N1. The first transistor M1 may control a driving current supplied to the light emitting element LD in response to a voltage of the first node N1. The first transistor M1 may be a driving transistor.

In an embodiment, at a lower portion of the first transistor M1 (for example, the gate electrode of the first transistor M1), a sync electrode layer CYNC to which an anode signal supplied to the light emitting element LD is applied by being electrically connected to the second node N2 may be disposed.

The second transistor M2 may be electrically connected between the data line DL and the first node N1. A second gate electrode GE2 (see FIG. 5) of the second transistor M2 may be electrically connected to the scan line SL. In case that a first scan signal of a gate-on voltage (for example, a high level voltage) is supplied from the scan line SL, the second transistor M2 may be turned on to electrically connect the data line DL and the first node N1.

For each frame period, a data signal of the corresponding frame is supplied to the data line DL, and the data signal is transmitted to the first node N1 through the second transistor M2 during a period in which the first scan signal of the gate-on voltage is supplied. The second transistor M2 may be a switching transistor for transmitting each data signal to the inside of the sub-pixel SPX.

One electrode of the storage capacitor CST may be electrically connected to the first node N1, and the other electrode thereof may be electrically connected to the second node N2. The storage capacitor CST is charged with a voltage corresponding to the data signal supplied to the first node N1 during each frame period.

The third transistor M3 may be electrically connected between the second node N2 and the sensing line SENL. A third gate electrode GE3 (see FIG. 5) of the third transistor M3 may be connected to the control line SSL (or the scan line SL). The third transistor M3 may be turned on in case that the second scan signal (or first scan signal) of a gate-on voltage (for example, a high level voltage) is supplied from the control line SSL to transmit the reference voltage (or initialization voltage) supplied to the sensing line SENL to the second node N2 or to transmit the voltage of the second node N2 to the sensing line SENL. The voltage of the second node N2 transmitted to the sensing circuit through the sensing line SENL may be supplied to an external circuit (for example, the controller 140) to be used to compensate for characteristic deviation of the sub-pixels SPX.

In FIG. 3, all of the transistors comprised in the pixel circuit PXC are illustrated as N-type transistors, but the disclosure is not limited thereto. For example, at least one of the first, second, and third transistors M1, M2, and M3 may be changed to a P-type transistor. The structure and driving method of the sub-pixel SPX may be variously changed according embodiments.

The light emitting element LD may be electrically connected between the first power line PL1 and the second power line PL2. For example, the second electrode ELT2 of the light emitting element LD may be electrically connected to the pixel circuit PXC, and the first electrode ELT1 of the light emitting element LD may be electrically connected to the second power line PL2.

The power of the first power line PL1 and the power of the second power line PL2 may have different potentials. For example, the power of the first power line PL1 may be a high-potential pixel power supplied from a first power supply VDD, and the power of the second power line PL2 may be a low-potential pixel power supplied from a second power supply VSS. A potential difference between the power of the first power line PL1 and the power of the second power line PL2 may be set to a threshold voltage or higher of the light emitting elements LD.

The first power line PL1 may be electrically connected to the first transistor M1. The second power line PL2 may be electrically connected to the cathode electrode (for example, the first electrode ELT1) of the light emitting element LD.

Each light emitting element LD may be connected in a forward direction between the first power line PL1 and the second power line PL2 to form each effective light source. These effective light sources may be collected to configure the light emitting elements LD of the sub-pixel SPX.

The light emitting elements LD may emit light with luminance corresponding to a driving current supplied through the pixel circuit PXC. During each frame period, the pixel circuit PXC may supply a driving current corresponding to the data signal to the light emitting element LD. The light emitting element LD may emit light with a luminance corresponding to a current flowing therethrough.

The pixel circuit PXC for the sub-pixel SPX according to the embodiment is not limited to the above-described example. In an embodiment, the pixel circuit PXC may further comprise seven transistors and one storage capacitor.

Hereinafter, structures of electrodes of the display device 1 according to the embodiment will be described with reference to FIG. 4 to FIG. 12. Descriptions that may be redundant to those described above are simplified or are not repeated.

FIG. 4 illustrates a schematic cross-sectional view of a stacked structure of a display device according to an embodiment. Referring to FIG. 4, a stacked structure comprised in the display device 1 (for example, the pixel circuit layer PCL) according to the embodiment may have at least a partially patterned structure in which a base layer BSL, a lower auxiliary electrode layer BML, a buffer layer BFL, an active layer ACT, a gate insulating layer GI, an interlayer insulating layer ILD, and a passivation layer PSV may be sequentially stacked each other. For example, the aforementioned electrode layers may be patterned according to one structure to form the pixel circuit PXC. The electrode layers described above may be patterned according to one structure to form some of the first power line PL1 and the second power line PL2.

The base layer BSL may form (or configure) a base surface of the display device 1. As described above, the base layer BSL may comprise various materials, and examples thereof are not particularly limited.

The buffer layer BFL may be a layer for preventing diffusion of impurities or moisture permeation into the active layer ACT comprising a semiconductor. In an embodiment, the buffer layer BFL may comprise one or more of a silicon nitride (SiNₓ), a silicon oxide (SiOₓ), a silicon oxynitride (SiOₓN_{y}), and an aluminum oxide (AlₓO_{y}). However, the disclosure is not necessarily limited to the example described above.

The active layer ACT may comprise a semiconductor. For example, the active layer ACT may comprise one or more of a polysilicon, a low temperature polycrystalline silicon (LTPS), an amorphous silicon, and an oxide semiconductor. In an embodiment, the active layer ACT may form channels of the first transistor M1, the second transistor M2, and the third transistor M3, and as a portion of the interlayer conductive layer ICL, impurities may be doped on a portion thereof in contact with the source electrode or the drain electrode of each of the first transistor M1, the second transistor M2, and the third transistor M3.

The lower auxiliary electrode layer BML and the interlayer conductive layer ICL may comprise a conductive material. According to the embodiment, each of the lower auxiliary electrode layer BML and the interlayer conductive layer ICL may comprise one or more conductive layers. According to the embodiment, each of the lower auxiliary electrode layer BML and the interlayer conductive layer ICL may comprise one or more of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not necessarily limited to the example described above.

The gate insulating layer GI, the interlayer insulating layer ILD, and the passivation layer PSV may be disposed between respective layers to electrically separate the active layer ACT and the interlayer conductive layer ICL from each other. According to the embodiment, the layers may be electrically connected to each other through a contact member CNP (see FIG. 5) formed on one or more of the gate insulating layer GI, the interlayer insulating layer ILD, and the passivation layer PSV.

According to the embodiment, the gate insulating layer GI, the interlayer insulating layer ILD, and/or the passivation layer PSV may comprise one or more of a silicon nitride (SiNₓ), a silicon oxide (SiOₓ), a silicon oxynitride (SiOₓN_{y}), and an aluminum oxide (AlₓO_{y}). However, the disclosure is not necessarily limited to the example described above. In an embodiment, the gate insulating layer GI, the interlayer insulating layer ILD, and/or the passivation layer PSV may comprise an organic material.

In an embodiment, the passivation layer PSV may be a via layer. The passivation layer PSV may be an uppermost layer of the pixel circuit layer PCL. The passivation layer PSV may be a layer directly adjacent to the light-emitting-element layer EML. According to the embodiment, the passivation layer PSV may cover the first gate electrode GE1. According to the embodiment, the passivation layer PSV may contact the first electrode ELT1 and the first gate electrode GE1 of the light-emitting-element layer EML.

The display device 1 according to an embodiment will be described with reference to FIG. 5 to FIG. 9.

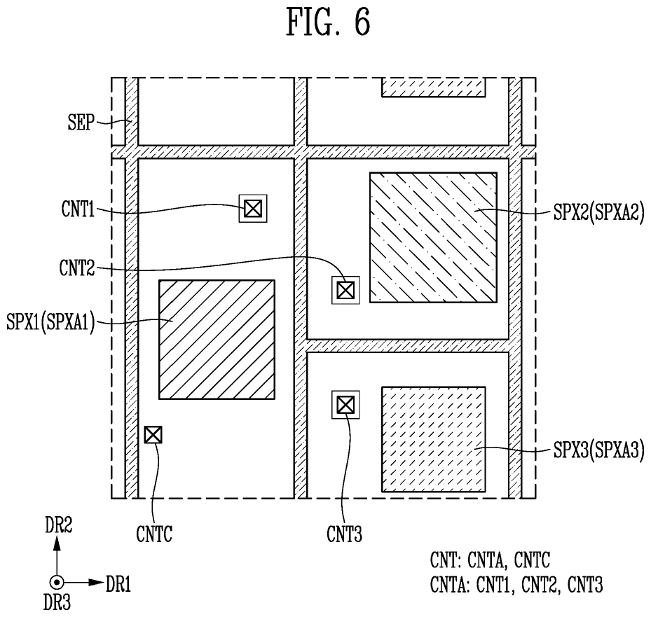

First, a planar structure of electrodes for forming the pixel circuit layer PCL will be described with reference to FIG. 5 and FIG. 6. In the following drawings, the same layers (for example, patterning in the same process) as the layers described above with reference to FIG. 4 may be represented by the same hatching.

FIG. 5 and FIG. 6 illustrate schematic plan views of an electrode structure according to an embodiment. FIG. 5 illustrates the lower auxiliary electrode layer BML, the active layer ACT, and the interlayer conductive layer ICL. FIG. 6 illustrates an anode contact portion CNTA and a cathode contact portion CNTC to clearly explain the positions of the first electrode ELT1 and the pixel defining film PDL of the light emitting element LD, but does not illustrate the lower auxiliary electrode layer BML, the active layer ACT, and the interlayer conductive layer ICL. Referring to FIG. 5 and FIG. 6 together, the position of each constituent element will be clearly understood.

In FIG. 5 and FIG. 6, a contact portion CNT is illustrated to have a shape in which an X is indicated in a quadrangular shape. The contact portion CNT has a structure formed in the passivation layer PSV (for example, penetrating the passivation layer PSV), and may be a connection member between a conductive layer in the pixel circuit layer PCL and a conductive layer in the light-emitting-element layer EML.

In an embodiment, the contact portion CNT may comprise the anode contact portion CNTA and the cathode contact portion CNTC. The anode contact portion CNTA may comprise a first contact portion CNT1, a second contact portion CNT2, and a third contact portion CNT3.

In FIG. 5 and FIG. 6, contact members CNP for electrically connecting different patterns (for example, the lower auxiliary electrode layer BML, the active layer ACT, and the interlayer conductive layer ICL) are illustrated to have a shape in which an X is indicated in a quadrangular shape.

In an embodiment, the pixel circuits PXC and lines connected to the pixel circuits PXC may be disposed (or patterned).

For example, the pixel circuit PXC may comprise a first pixel circuit PXC1, a second pixel circuit PXC2, and a third pixel circuit PXC3. Each of the first pixel circuit PXC1, the second pixel circuit PXC2, and the third pixel circuit PXC3 may comprise the first transistor M1, the second transistor M2, the third transistor M3, and the storage capacitor CST.

The first pixel circuit PXC1, the second pixel circuit PXC2, and the third pixel circuit PXC3 may be spaced apart from each other along the second direction DR2.

Each of the first pixel circuit PXC1, the second pixel circuit PXC2, and the third pixel circuit PXC3 may be the pixel circuit PXC for each of different sub-pixels SPX. For example, the first pixel circuit PXC1 may be the pixel circuit PXC for the first sub-pixel SPX1. The second pixel circuit PXC2 may be the pixel circuit PXC for the second sub-pixel SPX2. The third pixel circuit PXC3 may be the pixel circuit PXC for the third sub-pixel SPX3.

In an embodiment, the first transistor M1 of each of the first pixel circuit PXC1, the second pixel circuit PXC2, and the third pixel circuit PXC3 may comprise a first source electrode SE1, a first gate electrode GE1, a first drain electrode DE1, and a first active layer ACT1.

In an embodiment, the second transistor M2 of each of the first pixel circuit PXC1, the second pixel circuit PXC2, and the third pixel circuit PXC3 may comprise a second source electrode SE2, a second gate electrode GE2, a second drain electrode DE2, and a second active layer ACT2.

In an embodiment, the third transistor M3 of each of the first pixel circuit PXC1, the second pixel circuit PXC2, and the third pixel circuit PXC3 may comprise a third source electrode SE3, a third gate electrode GE3, a third drain electrode DE3, and a third active layer ACT3.

In an embodiment, the first gate electrode GE1 may be an uppermost conductive layer of the pixel circuit layer PCL in an area in which the first gate electrode GE1 is disposed. For example, a conductive layer may not be disposed between a boundary line between the pixel circuit layer PCL and the light-emitting-element layer EML and the first gate electrode GE1. The first gate electrode GE1 may be covered by an insulating layer (for example, the passivation layer PSV) disposed on the uppermost portion of the pixel circuit layer PCL. A conductive layer may not be disposed between the first gate electrode GE1 and the light-emitting-element layer EML.

In an embodiment, among the electrodes to which the gate signal for the first transistor M1 is applied, an electrode layer formed at the outermost portion of the pixel circuit layer PCL may not overlap the first electrode ELT1 in a plan view. For example, at least a portion of the first gate electrode GE1 formed by the interlayer conductive layer ICL may not overlap the first electrode ELT1 in a plan view.

In an embodiment, the first electrode ELT1 may form an open area OA. The opening (or, open) area OA may not overlap at least a portion of the first gate electrode GE1 formed by the interlayer conductive layer ICL in a plan view. The opening area OA may mean an area in which the first electrode ELT1 is not disposed.

Experimentally, in case that the conductive path to which the gate signal is applied is directly adjacent to the first electrode ELT1 to which the cathode signal is supplied, there is a risk of formation of coupling capacitance between both electrodes.

Experimentally, in case that the coupling capacitance occurs, the electrical signal supplied to the sub-pixel SPX may be distorted, and the signal delay may cause horizontal crosstalk and color deviation. However, according to the embodiment, at least a partial area of the first gate electrode GE1 is disposed so as to not overlap the first electrode ELT1 to prevent the formation of coupling capacitance, thereby improving the reliability of electrical signals and preventing horizontal crosstalk and color deviation.

In an embodiment, a shape of the opening area OA and a shape of the first gate electrode GE1 may correspond to each other. For example, the opening area OA may be disposed to surround an edge of the first gate electrode GE1. The opening area OA may be defined to be adjacent to the edge of the first gate electrode GE1. For example, the shape of the opening area OA and the shape of the first gate electrode GE1 may be substantially the same. For example, the shape of the opening area OA and the shape of the first gate electrode GE1 may each have a shape comprising a single bending portion.

In case that an area of the first electrode ELT1 is reduced, a value of resistance defined by the first electrode ELT1 may be increased. According to the embodiment, the shape of the opening area OA may be provided to correspond to the shape of the first gate electrode GE1, so that the formation of the aforementioned coupling capacitance may be prevented, and an increase in the resistance of the first electrode ELT1 may be minimized.

In an embodiment, the first electrode ELT1 may form a peripheral opening area OA′. The peripheral opening area OA′ may surround the anode contact portion CNTA when viewed from a plan view. The peripheral opening area OA′ may be disposed at a peripheral portion of the anode contact portion CNTA when viewed from a plan view.

The storage capacitor CST may comprise an upper electrode UE and a lower electrode LE. According to the embodiment, the upper electrode UE may be formed by the active layer ACT, and the lower electrode LE may be formed by the lower auxiliary electrode layer BML. However, the disclosure is not necessarily limited to the example described above. According to the embodiment, the upper electrode UE may be formed of one or more layers (for example, the interlayer conductive layer ICL, and the like) disposed above the auxiliary lower electrode layer BML.

According to the embodiment, the storage capacitor CST of the first pixel circuit PXC1, the storage capacitor CST of the second pixel circuit PXC2, and the storage capacitor CST of the third pixel circuit PXC3 may be sequentially disposed along the second direction DR2.

The first scan line SL1 among the scan lines SL may extend in the first direction DR1. The second scan line SL2 among the scan lines SL may extend in the second direction DR2. The first scan line SL1 and the second scan line SL2 may be formed by one conductive layer(s). For example, the first scan line SL1 and the second scan line SL2 may be formed by the interlayer conductive layer ICL.

The data lines DL may extend in the second direction DR2. The data lines DL may be spaced apart from each other in the first direction DR1. The data lines DL may comprise a first data line DL1, a second data line DL2, and a third data line DL3.

The first data line DL1 is a data line for the first pixel circuit PXC1, and may be electrically connected to the second drain electrode DE2 of the second transistor M2 of the first pixel circuit PXC1. The second data line DL2 is a data line for the second pixel circuit PXC2, and may be electrically connected to the second drain electrode DE2 of the second transistor M2 of the second pixel circuit PXC2. The third data line DL3 is a data line for the third pixel circuit PXC3, and may be electrically connected to the second drain electrode DE2 of the second transistor M2 of the third pixel circuit PXC3.

The sensing line SENL may extend in the second direction DR2. The sensing line SENL may be electrically connected to the third drain electrode DE3 of the third transistor M3 of the first to third pixel circuits PXC1, PXC2, and PXC3.

The first power line PL1 receiving power from the first power source VDD may extend in the second direction DR2, and may be electrically connected to the first drain electrode DE1 of the first transistor M1 of the first to third pixel circuits PXC1, PXC2, and PXC3.

The first power line PL1 may be electrically connected to the anode electrode (for example, the second electrode ELT2) of each sub-pixel SPX through the first transistor M1 and the anode contact portion CNTA. For example, the first contact portion CNT1 may be electrically connected to the second electrode ELT2 of the first sub-pixel SPX1. The second contact portion CNT2 may be electrically connected to the second electrode ELT2 of the second sub-pixel SPX2. The third contact portion CNT3 may be electrically connected to the second electrode ELT2 of the third sub-pixel SPX3.

The second power line PL2 receiving power from the second power supply VSS may comprise a (2-1)-th power line PL2-1 extending in the first direction DR1 and a (2-2)-th power line (PL2-2) extending in the second direction DR2. The (2-1)-th power line PL2-1 and the (2-2)-th power line PL2-2 may be electrically connected through one contact member CNP.

The second power line PL2 may be electrically connected to the cathode electrode (for example, the first electrode ELT1) through the cathode contact portion CNTC.

The first electrode ELT1 may be the cathode electrode for the sub-pixels SPX. The first electrode ELT1 may be disposed across areas in which the sub-pixels SPX are disposed. The first electrode ELT1 may be electrically connected to a portion of the second power line PL2. Accordingly, the first electrode ELT1 may be configured to receive a cathode signal.

The second electrode ELT2 may be an anode electrode of each of the first to third sub-pixels SPX1, SPX2, and SPX3. Accordingly, respective second electrodes ELT2 of the first to third sub-pixels SPX1, SPX2, and SPX3 may be spaced apart from each other to respectively receive the anode signal from the first to third pixel circuits PXC1, PXC2, and PXC3.

The second electrode ELT2 may be electrically connected to the first source electrode SE1 of the first transistor M1 through the anode contact portion CNTA. Accordingly, the second electrode ELT2 may be configured to receive a driving signal.

In an embodiment, the display device 1 may further comprise a separator SEP. The separator SEP may be disposed at the periphery of the sub-pixels SPX. For example, each of the sub-pixels SPX may form a sub-pixel area SPXA. The sub-pixel areas SPXA may comprise a first sub-pixel area SPXA1 formed by the first sub-pixel SPX1, a second sub-pixel area SPX2 formed by the second sub-pixel SPX2, and a third sub-pixel area SPX3 formed by the third sub-pixel SPX3.

The separator SEP may be disposed around the first to third sub-pixel areas SPXA1, SPXA2, and SPXA3.

The separator SEP may have a structure for separating the anode electrodes of each sub-pixel SPX. For example, the second electrode ELT2 of each of the sub-pixels SPX may be electrically separated based on the separator SEP.

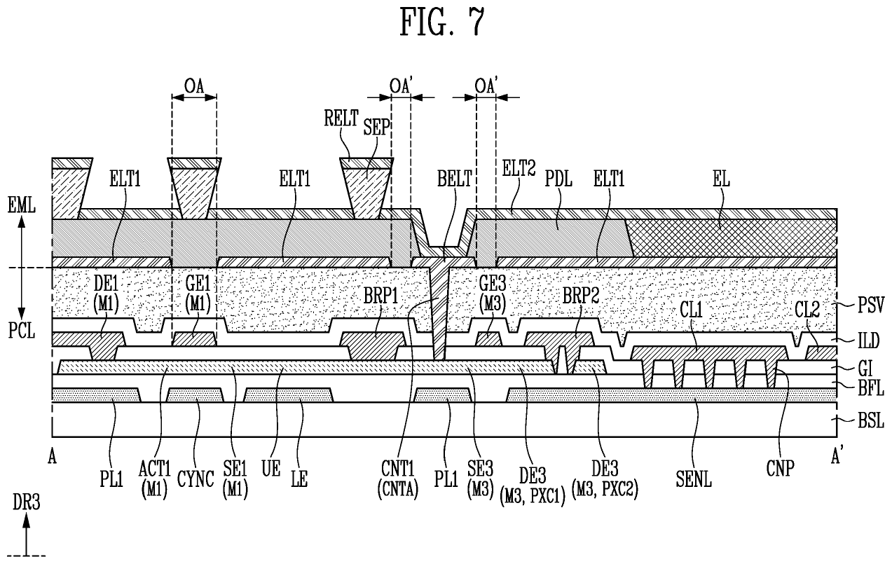

A structure between electrodes according to the first embodiment will be described with reference to FIG. 7 to FIG. 9. Descriptions that may be redundant to those described above are simplified or are not repeated.

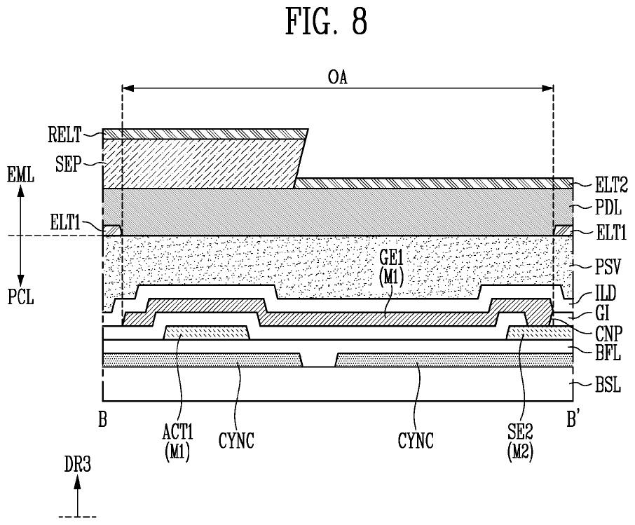

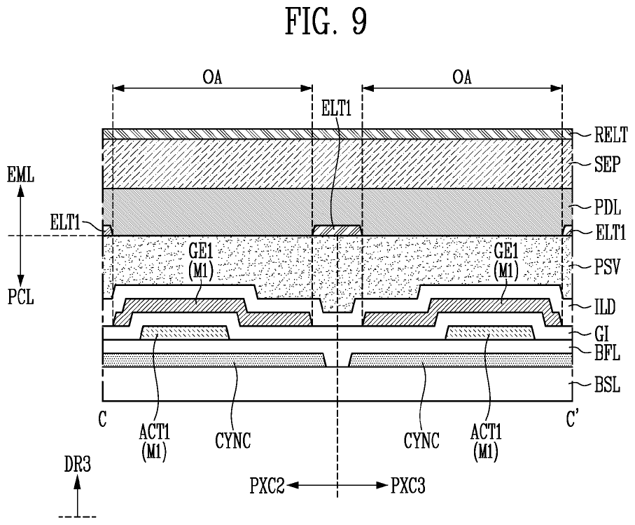

FIG. 7 to FIG. 9 illustrate schematic cross-sectional views of a display device according to an embodiment. FIG. 7 illustrates a schematic cross-sectional view taken along line A-A′ of FIG. 5. FIG. 8 illustrates a schematic cross-sectional view taken along line B-B′ of FIG. 5. FIG. 9 illustrates a schematic cross-sectional view taken along line C-C′ of FIG. 5.

Referring to FIG. 7 to FIG. 9, electrode patterns form a connection structure of the pixel circuit PXC, and form an electrical path to which an electrical signal is applied.

The display device 1 according to the embodiment may comprise the pixel circuit layer PCL, and the light-emitting-element layer EML on the pixel circuit layer PCL.

In an embodiment, the lower auxiliary electrode layer BML disposed on the base layer BSL may form the first power line PL1, the sync conductive layer CYNC, the lower electrode LE, and the sensing line SENL.

In an embodiment, the sync conductive layer CYNC may overlap the first active layer ACT1 and the first gate electrode GE1 of the first transistor M1 in a plan view.

According to the embodiment, the active layer ACT may form the first active layer ACT1, the second active layer ACT2, at least a portion of the first source electrode SE1, at least a portion of the third source electrode SE3, and at least a portion of the third drain electrode DE3.

In an embodiment, the first source electrode SE1 may be electrically connected to a bridge electrode layer BELT through the anode contact portion CNTA (for example, the first contact portion CNT1). The bridge electrode layer BELT may be formed in the same process as the first electrode ELT1, and may be disposed on the same layer to comprise the same material or a similar material. The bridge electrode layer BELT may be electrically connected to the second electrode ELT2. Accordingly, the anode signal supplied through the first source electrode SE1 may be supplied to the second electrode ELT2 through the bridge electrode layer BELT.

In an embodiment, the anode contact portion CNTA may be surrounded by the peripheral opening area OA′ in a plan view. For example, the first electrode ELT1 and the bridge electrode layer BELT may not be disposed in at least a partial area, and may form the peripheral opening area OA′. The peripheral opening area OA′ may not overlap the anode contact portion CNTA when viewed from a plan view. The peripheral opening area OA′ may be disposed at the peripheral portion of the anode contact portion CNTA when viewed from a plan view. As the peripheral opening area OA′ is formed, the anode signal to be supplied to the second electrode ELT2 may be applied to the bridge electrode layer BELT without being applied to the first electrode ELT1.

In an embodiment, the interlayer conductive layer ICL may form a first drain electrode DE1, a first gate electrode GE1, a first bridge pattern BRP1, a third gate electrode GE3, a second bridge pattern BRP2, a first conductive line CL1, and a second conductive line CL2.

The first gate electrode GE1 may overlap the first active layer ACT1 in a plan view. The first gate electrode GE1 may be electrically connected to the second source electrode SE2.

According to the embodiment, the first gate electrode GE1 is a layer formed by the interlayer conductive layer ICL, and may be electrically connected to the second source electrode SE2 through the contact member CNP. For example, the first gate electrode GE1 is a layer formed by the interlayer conductive layer ICL, and may be directly electrically connected to second source electrode SE2 through the contact member CNP without passing through another conductive layer. In an embodiment, the first gate electrode GE1 may further overlap the sync conductive layer CYNC.

The first gate electrode GE1 may not overlap the first electrode ELT1 in a plan view. The first gate electrode GE1 may overlap the opening area OA in a plan view.

For example, the opening area OA may be disposed at the periphery of the first gate electrode GE1 in a plan view. The opening area OA may entirely cover the first electrode ELT1 in a plan view.

In the pixel circuit layer PCL, another conductive layer may not be disposed in an upper area of the first gate electrode GE1. For example, a portion of the interlayer conductive layer ICL forming the first gate electrode GE1 may be an uppermost conductive layer in the pixel circuit layer PCL.

At least a portion of the first gate electrode GE1 may comprise a surface facing the light-emitting-element layer EML. At least a portion of the first gate electrode GE1 may form a surface facing the light-emitting-element layer EML without a conductive layer interposed therebetween.

In an embodiment, the first gate electrode GE1 (for example, at least a portion of the first gate electrode GE1 formed by the interlayer conductive layer ICL) may overlap the second electrode ELT2 in a plan view. The first gate electrode GE1 may form an opposite surface to the second electrode ELT2. The first gate electrode GE1 and the second electrode ELT2 may form a capacitance. For example, the second electrode ELT2 may receive the anode signal, and may form the same potential as the lower electrode LE of the storage capacitor CST. In an embodiment, the first gate electrode GE1 may form the same potential as the upper electrode UE of the storage capacitor CST. Accordingly, the first gate electrode GE1 and the second electrode ELT2 may form capacitance.

Experimentally, in order to secure one capacitance in each sub-pixel SPX, the area between the upper electrode UE and the lower electrode LE needs to be increased, and the area of the pixel circuit PXC may be increased. However, according to the embodiment, the first gate electrode GE1 may form capacitance with the second electrode ELT2 for supplying the anode signal, thereby reducing the complexity of the pixel circuit PXC.

The first bridge pattern BRP1 may be electrically connected to the upper electrode UE and the third source electrode SE3. The second bridge pattern BRP2 may be electrically connected to the third drain electrode DE3.

The first conductive line CL1 may be electrically connected to the sensing line SENL. The second conductive line CL2 may electrically connect the sensing line SENL and the third drain electrode DE3.

In an embodiment, the first electrode ELT1 may be configured to receive the cathode signal, and may be disposed on the passivation layer PSV. The first electrode ELT1 may not be disposed in a partial area, and may form the opening area OA and the peripheral opening area OA′. The first electrode ELT1 may not overlap the first gate electrode GE1 in a plan view.

In an embodiment, the bridge electrode layer BELT may be disposed on the same layer as the first electrode ELT1, and may be surrounded by the peripheral opening area OA′. The bridge electrode layer BELT may electrically connect the first and third source electrodes SE1 and SE3 and the second electrode ELT2.

The pixel defining film PDL and the light emitting layer EL may be disposed on the first electrode ELT1. The second electrode ELT2 may be disposed on the pixel defining film PDL and the light emitting layer EL.

In an embodiment, the separator SEP may be disposed on the pixel defining film PDL. The separator SEP may comprise at least one of an acrylic resin, an epoxy resin, a phenol resin, a polyamide resin, and a polyimide resin. However, the disclosure is not limited thereto.

The separator SEP may have a substantially under-cut shape, and an upper side thereof may have a substantially large cross-sectional area. In case that depositing the conductive layer for forming the second electrode ELT2, the deposited conductive layers may be spaced apart from each other with the separator SEP interposed therebetween.

For example, the display device 1 may further comprise a residual conductive layer RELT disposed on the separator SEP as a layer formed in the same process as the second electrode ELT2 and comprising the same material or a similar material.

The residual conductive layer RELT may be disposed on the upper surface of the separator SEP, and may be physically separated from the second electrode ELT2 adjacent to the separator SEP. Accordingly, the second electrode ELT2 for respective sub-pixels SPX may be configured to receive different anode signals from each other.

In an embodiment, the residual conductive layer RELT may overlap the first gate electrode GE1 in a plan view. The residual conductive layer RELT may overlap the opening area OA in a plan view.

In an embodiment, the separator SEP may overlap the first gate electrode GE1 in a plan view. The separator SEP may overlap the opening area OA in a plan view.

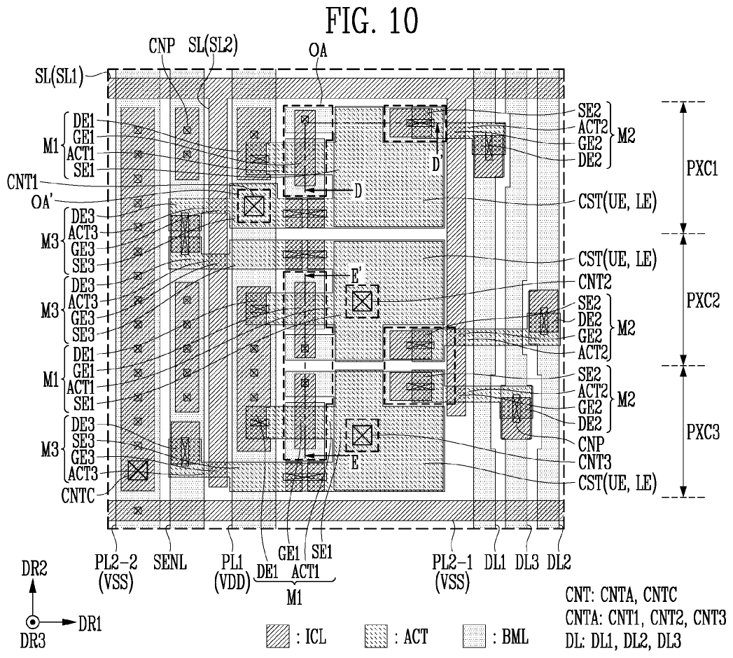

The display device 1 according to an embodiment will be described with reference to FIG. 10 to FIG. 12. Descriptions that may be redundant to those described above are simplified or may not be repeated.

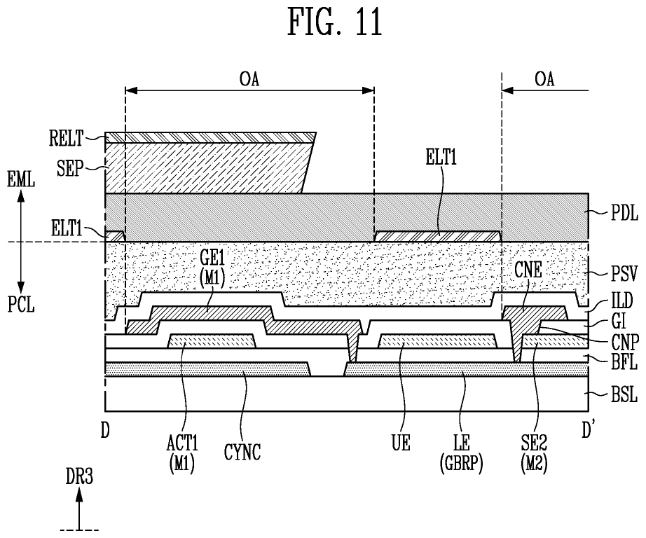

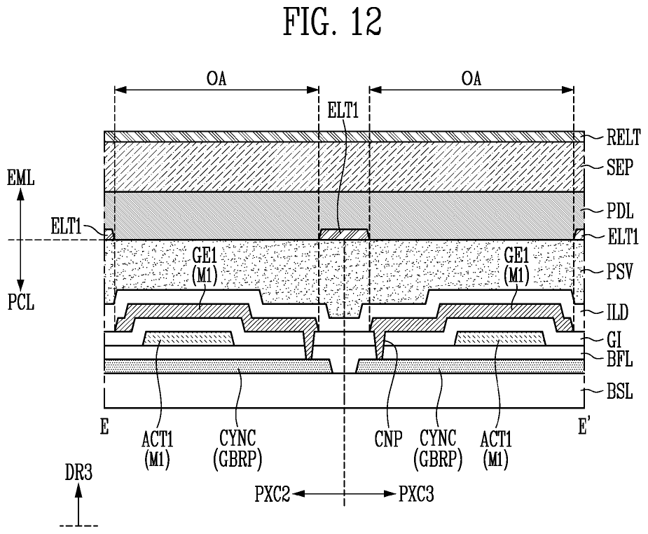

FIG. 10 illustrates a schematic top plan view of an electrode structure according to an embodiment. FIG. 11 and FIG. 12 illustrate schematic cross-sectional views of a display device according to an embodiment. FIG. 11 illustrates a schematic cross-sectional view taken along line D-D′ of FIG. 10. FIG. 12 illustrates a schematic cross-sectional view taken along line E-E′ of FIG. 10.

The display device 1 according to the second embodiment is different from display device 1 according to the first embodiment in that the first gate electrode GE1 is electrically connected to the second source electrode SE2 through a gate bridge GBRP.

Similarly, in an embodiment, at least a portion of the first gate electrode GE1 formed by the interlayer conductive layer ICL may overlap the opening area OA in a plan view.

In an embodiment, the first gate electrode GE1 may be electrically connected to the second source electrode SE2 through another conductive layer. The first gate electrode GE1 may not be directly electrically connected to the second source electrode SE2, but may be electrically connected thereto through the gate bridge GBRP that is disposed below the first gate electrode GE1 (for example, that is closer to the base layer BSL).

For example, the first gate electrode GE1 may be electrically connected to the second source electrode SE2 through the gate bridge GBRP formed by the lower auxiliary electrode layer BML and the connection electrode layer CNE formed by the interlayer conductive layer ICL.

In an embodiment, the gate bridge GBRP may be integral with the lower electrode LE. In an embodiment, the gate bridge GBRP may be integral with the sync conductive layer CYNC.

According to an embodiment, at least a portion of the electrode layer to which the first gate signal to the first transistor M1 is applied may be covered by another conductive layer (for example, the upper electrode UE as a portion of the active layer ACT). Accordingly, the formation of parasitic capacitance between the electrode layer to which the first gate signal is applied and the first electrode ELT1 to which the cathode signal is applied may be minimized.

While the disclosure has been shown and described with reference to embodiments thereof, it will be understood by those skilled in the art that various changes in forms and details may be made therein without departing from the spirit and scope of the disclosure and as defined by the appended claims and their equivalents.

Therefore, the technical scope of the disclosure may be determined by the above and on the technical scope of the accompanying claims.

What is claimed is:

1. A display device comprising:
a pixel circuit layer comprising a base layer and a pixel circuit; and
a light emitting element disposed on the pixel circuit layer and comprising:
a first electrode;
a second electrode; and
a light emitting layer electrically connected the first electrode and the second electrode, wherein
the pixel circuit comprises a first transistor,
the first transistor comprises:
a first gate electrode;
a first active layer;
a first source electrode; and
a first drain electrode,
the first electrode forms an open area, and
the first gate electrode and the open area overlap each other in a plan view.

2. The display device of claim 1, wherein
the first gate electrode is an uppermost conductive layer of the pixel circuit layer in an area including the first gate electrode.

3. The display device of claim 2, wherein
the pixel circuit layer comprises:
a lower auxiliary electrode layer;
an active layer; and
an interlayer conductive layer that form the pixel circuit,
the lower auxiliary electrode layer is closer to the base layer than the interlayer conductive layer, and
at least a portion of the first gate electrode is formed by the interlayer conductive layer.

4. The display device of claim 1, wherein
the first gate electrode overlaps the second electrode in a plan view.

5. The display device of claim 4, wherein
the first gate electrode forms a capacitance with the second electrode.

6. The display device of claim 1, further comprising:
a bridge electrode layer, the bridge electrode layer and the first electrode being disposed on a same layer and electrically connected to each other, wherein
the first electrode forms a peripheral opening area, and
the peripheral opening area surrounds the bridge electrode layer.

7. The display device of claim 3, wherein
the pixel circuit comprises a second transistor including a second gate electrode, a second active layer, a second source electrode, and a second drain electrode, and
the second source electrode is electrically connected to the first gate electrode.

8. The display device of claim 7, wherein
the first gate electrode is electrically connected to the second source electrode without passing through a conductive layer disposed on a different layer from a layer of the first gate electrode.

9. The display device of claim 7, wherein
the pixel circuit further comprises a gate bridge formed by the lower auxiliary electrode layer, and
the first gate electrode is electrically connected to the second source electrode through the gate bridge.

10. The display device of claim 9, wherein
the pixel circuit further comprises a connection electrode layer formed by the interlayer conductive layer, and
the connection electrode layer, the gate bridge, and the second source electrode are electrically connected to each other.

11. The display device of claim 7, wherein
the first transistor is a driving transistor, and
the second transistor is a switching transistor.

12. The display device of claim 11, further comprising:
a first power line and a second power line disposed on the base layer, wherein
the pixel circuit comprises a third transistor including a third gate electrode, a third active layer, a third source electrode, and a third drain electrode,
the third source electrode is electrically connected to the first source electrode,
the first power line is electrically connected to the pixel circuit,
the pixel circuit is electrically connected to the second electrode, and
the second power line is electrically connected to the first electrode.

13. The display device of claim 12, wherein:
the pixel circuit comprises a first pixel circuit of a first sub-pixel, a second pixel circuit of a second sub-pixel, and a third pixel circuit of a third sub-pixel,
the first power line extends in a first direction,
the second power line comprises a (2-1)-th power line extending in the first direction and a (2-2)-th power line extending in a second direction different from the first direction,
the pixel circuit comprises a storage capacitor, and
respective storage capacitors of the first pixel circuit, the second pixel circuit, and the pixel circuit are sequentially disposed in the second direction.

14. The display device of claim 1, wherein
a shape of the open area corresponds to a shape of the first gate electrode.

15. The display device of claim 14, wherein
a shape of the open area is substantially the same as a shape of the first gate electrode.

16. The display device of claim 1, wherein
the first electrode is a cathode electrode electrically connected to the light emitting layer,
the second electrode is an anode electrode electrically connected to the light emitting layer, and
the first electrode is disposed between the second electrode and the base layer.

17. The display device of claim 1, further comprising:
a pixel defining film disposed on the pixel circuit layer;
a separator disposed on the pixel defining film and having a substantially under-cut shape; and
a residual conductive layer disposed on the separator, wherein
the residual conductive layer and the second electrode comprise a same material,
the residual conductive layer and the second electrode are physically spaced apart from each other, and
the separator overlaps the first gate electrode and the open area in a plan view.

18. The display device of claim 1, wherein
the light emitting element is an organic light emitting diode (OLED).

19. A display device comprising:
a pixel circuit layer comprising a base layer and a pixel circuit disposed on the base layer; and
a light-emitting-element layer comprising a light emitting element disposed on the pixel circuit layer and comprising a cathode electrode, an anode electrode, and a light emitting layer electrically connected to the cathode electrode and the anode electrode, wherein
the pixel circuit layer comprises a lower auxiliary electrode layer, an active layer, and an interlayer conductive layer,
the interlayer conductive layer is closer to the light-emitting-element layer than the lower auxiliary electrode layer,
the pixel circuit comprises a first transistor and a second transistor,
the first transistor comprises a first gate electrode, a first active layer, a first source electrode, and a first drain electrode,
the second transistor comprises a second gate electrode, a second active layer, a second source electrode, and a second drain electrode,
the second source electrode is electrically connected to the first gate electrode,
the first gate electrode and the second gate electrode are formed by the interlayer conductive layer,
the first active layer and the second active layer are formed by the active layer, and
the cathode electrode and at least a portion of the interlayer conductive layer forming the second gate electrode do not overlap each other in a plan view.

20. A display device comprising:
a pixel circuit layer comprising a base layer and a pixel circuit; and
a light emitting element disposed on the pixel circuit layer and comprising a first electrode, a second electrode, and a light emitting layer electrically connected to the first electrode and the second electrode, wherein
the pixel circuit comprises a driving transistor,
the first electrode forms an open area, and
the open area surrounds an edge of a gate electrode of the driving transistor in a plan view.
